(19) United States
(12) Patent Application Publication
(10) Pub. No.: US 2008/0246072 A1
(43) Pub. Date: Oct. 9, 2008

(54) NONVOLATILE SEMICONDUCTOR MEMORY DEVICE AND MANUFACTURING METHOD OF THE SAME

(75) Inventors: Masaki Kondo, Yokohama-shi (JP); Takashi Izumida, Yokohama-shi (JP); Nobutoshi Aoki, Yokohama-shi (JP); Toshiharu Watanabe, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/773,721

(22) Filed: Jul. 5, 2007

(30) Foreign Application Priority Data
Apr. 6, 2007 (JP) 2007-100124

(51) Int. Cl. H01L 29/788

(52) U.S. Cl. 257/314; 257/E29.3

(57) ABSTRACT

In a nonvolatile semiconductor memory device including a memory cell column formed by connecting in series a plurality of memory cells each having a structure in which a charge-storage layer and a control gate are stacked via an insulating layer on a semiconductor substrate, a first selection transistor formed on the semiconductor substrate and connected between one end of the memory cell column and a common source line, and a second selection transistor formed on the semiconductor substrate and connected between the other end of the memory cell column and a bit line, a recessed portion is formed on a surface of the semiconductor substrate between the first selection transistor and a memory cell adjacent to the first selection transistor, and an edge at a side of the first selection transistor in the recessed portion reaches an end portion at a side of the memory cell in a gate of the first selection transistor.

### CROSS-REFERENCE TO RELATED APPLICATION

This application is based upon and claims the benefit of prior Japanese Patent Application No. 2007-100124, filed on Apr. 6, 2007, the entire contents of which are incorporated herein by reference.

### BACKGROUND OF THE INVENTION

1. Field of the Invention

The present invention relates to a nonvolatile semiconductor memory device such as a NAND type flash memory, for example, and a manufacturing method of the same.

2. Description of the Related Art

Nonvolatile semiconductor memory devices which do not lose data even when power supplies are turned off are semiconductor devices which have been developed with the development of microcomputers, and such devices include NAND type flash memories.

A NAND type flash memory includes a NAND cell unit configured by a memory cell column constituted by connecting in series a plurality of memory cells each having a stack gate structure in which a floating gate as a charge-storage layer and a control gate are stacked, and a first selection transistor and a second selection transistor which are respectively connected between one end of the memory cell column and a common source line and between the other end of the memory cell column and a bit line.

When data write is performed in the NAND type flash memory, a write voltage is applied to the word line of the memory cell in which the data is written, and an intermediate voltage is applied to the word lines of the memory cells in which the data are not written. A predetermined positive voltage is applied to the common source line, and 0 V is applied to the gate of the selection transistor connected to the common source line. A predetermined positive voltage is applied to both of the bit line and the gate of the selection transistor connected to the bit line in the case of the bit line on which the data are not written.

On this occasion, both of the selection transistors are in off states, and channel potential of the memory cell column is boosted to positive voltage due to capacitive coupling between the floating gates of the memory cells and the channel. As a result, a memory cell adjacent to the selection transistor connected to the common source line receives an influence of a strong electric field in a lateral direction formed between the memory cell and the selection transistor, and electrons which are generated in the interface of the gate oxide film of the selection transistor and the silicon substrate become hot electrons which move to the adjacent memory cell along the surface of the silicon substrate. The hot electrons which thus generate flow into the floating gate of the memory cell adjacent to the selection transistor, and cause the phenomenon of programming the data of the adjacent memory cell, that is, erroneous write. This phenomenon occurs in the memory cell adjacent to the selection transistor, and hardly occurs in the other memory cells to which the memory cells are adjacent. The memory cell adjacent to the selection transistor and the memory cells other than this memory cell show different characteristics. This is due to the disturb phenomena which is caused by the above described hot electrons.

In order to prevent erroneous write in the memory cell adjacent to the selection transistor due to such a disturb phenomenon, Japanese Patent Laid-Open No. 2006-191017 discloses the invention relating to a NAND type flash memory with the configuration in which the distance between the selection transistor and the memory cell adjacent to this is increased. Japanese Patent Laid-Open No. 2006-186359 discloses the invention relating to a NAND type flash memory with the configuration in which a dummy memory cell is provided between the selection transistor and the memory cell adjacent to this. However, each of the inventions disclosed in these documents has the problem that the circuit area increases.

### SUMMARY OF THE INVENTION

A nonvolatile semiconductor memory device according to one embodiment of the present invention comprises a memory cell column formed by connecting in series a plurality of memory cells each having a structure in which a charge-storage layer and a control gate are stacked via an insulating layer on a semiconductor substrate, a first selection transistor formed on the aforesaid semiconductor substrate and connected between one end of the aforesaid memory cell column and a common source line, and a second selection transistor formed on the aforesaid semiconductor substrate and connected between the other end of the aforesaid memory cell column and a bit line, wherein a recessed portion is formed on a surface of the aforesaid semiconductor substrate between the aforesaid first selection transistor and a memory cell adjacent to the aforesaid first selection transistor, an edge at a side of the aforesaid first selection transistor in the aforesaid recessed portion reaches an end portion at a side of said memory cell in a gate of the aforesaid first selection transistor.

A nonvolatile semiconductor device according to another embodiment of the present invention comprises a memory cell column formed by connecting in series a plurality of memory cells each having a structure in which a charge-storage layer and a control gate are stacked via an insulating layer on a semiconductor substrate, a first selection transistor formed on the aforesaid semiconductor substrate and connected between one end of the aforesaid memory cell column and a common source line, and a second selection transistor formed on the aforesaid semiconductor substrate and connected between the other end of the aforesaid memory cell column and a bit line, wherein an impurity diffusion layer for supplying a carrier formed in the aforesaid semiconductor substrate between the aforesaid first selection transistor and a memory cell adjacent to the aforesaid first selection transistor is positioned in a deeper layer-separated from a surface of the aforesaid semiconductor substrate.

A nonvolatile semiconductor memory device according to still another embodiment of the present invention comprises a memory cell column formed by connecting in series a plurality of memory cells each having a structure in which a charge-storage layer and a control gate are stacked via an insulating layer on a semiconductor substrate, a first selection transistor formed on the aforesaid semiconductor substrate and connected between one end of the aforesaid memory cell column and a common source line, and a second selection transistor formed on the aforesaid semiconductor substrate and connected between the other end of the aforesaid memory cell column and a bit line, a write voltage being applied to a control gate of a selected memory cell of the aforesaid memory cell column, a pass voltage lower than the aforesaid write voltage being applied to a control gate of a non-selected memory cell of the aforesaid memory cell column, a ground voltage being applied to a gate of the aforesaid first selection transistor, a predetermined voltage which turns on or off said second selection transistor in accordance with data on the aforesaid bit line being applied to a gate of the aforesaid second selection transistor, and thereby the data on the aforesaid bit line being written in the aforesaid selected memory cell, wherein at least a part of a top surface of an impurity diffusion layer for supplying a carrier formed in said semiconductor substrate between the aforesaid first selection transistor and a memory cell adjacent to the aforesaid first selection transistor is deeper than a surface level of the aforesaid semiconductor substrate.

### BRIEF DESCRIPTION OF THE DRAWINGS

FIG. 1 is a circuit diagram of a NAND cell unit of a NAND type flash memory according to a first embodiment of the present invention;

FIG. 2 is a plan view of a cell region of the NAND type flash memory according to the first embodiment of the present invention;

FIG. 3 is a sectional view taken along the line I-I′ in FIG. 2;

FIG. 4 is a sectional view taken along the line II-II′ in FIG. 2;

FIG. 5 is a diagram showing the relation between the intermediate voltage Vpass applied to gates of the non-selected memory cells and the erroneous write rate;

FIG. 6 is a schematic view showing the state of occurrence of erroneous write on the occasion of boosting of a NAND type flash memory;

FIG. 7 is a sectional view showing the NAND type flash memory of the first embodiment of the present invention in the sequence of a manufacture process;

FIG. 8 is a sectional view showing the NAND type flash memory of the same first embodiment in the sequence of the manufacture process;

FIG. 9 is a sectional view showing the NAND type flash memory of the same first embodiment in the sequence of the manufacture process;

FIG. 10 is a sectional view showing the NAND type flash memory of the same first embodiment in the sequence of the manufacture process;

FIG. 11 is a sectional view showing the NAND type flash memory of the same first embodiment in the sequence of the manufacture process;

FIG. 12 is a sectional view showing the NAND type flash memory of the same first embodiment in the sequence of the manufacture process;

FIG. 13 is a sectional view showing the NAND type flash memory of the same first embodiment in the sequence of the manufacture process;

FIG. 14 is a sectional view showing the NAND type flash memory of the same first embodiment in the sequence of the manufacture process;

FIG. 15 is a sectional view of a NAND type flash memory according to a second embodiment of the present invention;

FIG. 16 is a sectional view showing the NAND type flash memory of the same second embodiment in the sequence of a manufacture process;

FIG. 17 is a sectional view showing the NAND type flash memory of the same second embodiment in the sequence of the manufacture process;

FIG. 18 is a sectional view of a NAND type flash memory according to a third embodiment of the present invention;

FIG. 19 is a sectional view showing the NAND type flash memory of the same third embodiment in the sequence of a manufacture process;

FIG. 20 is a sectional view showing the NAND type flash memory of the same third embodiment in the sequence of the manufacture process;

FIG. 21 is a sectional view showing the NAND type flash memory of the same third embodiment in the sequence of the manufacture process;

FIG. 22 is a sectional view showing the NAND type flash memory of the same third embodiment in the sequence of manufacture process;

FIG. 23 is a sectional view showing the NAND type flash memory of the same third embodiment in the sequence of the manufacture process;

FIG. 24 is a sectional view of a NAND type flash memory according to a fourth embodiment of the present invention;

FIG. 25 is a graph showing the simulated relation between the depth of an impurity diffusion layer and the BBT generation recombination amount in the same fourth embodiment; and

FIG. 26 is a sectional view of a NAND type flash memory according to a fifth embodiment of the present invention.

### DETAILED DESCRIPTION OF THE INVENTION

### First Embodiment

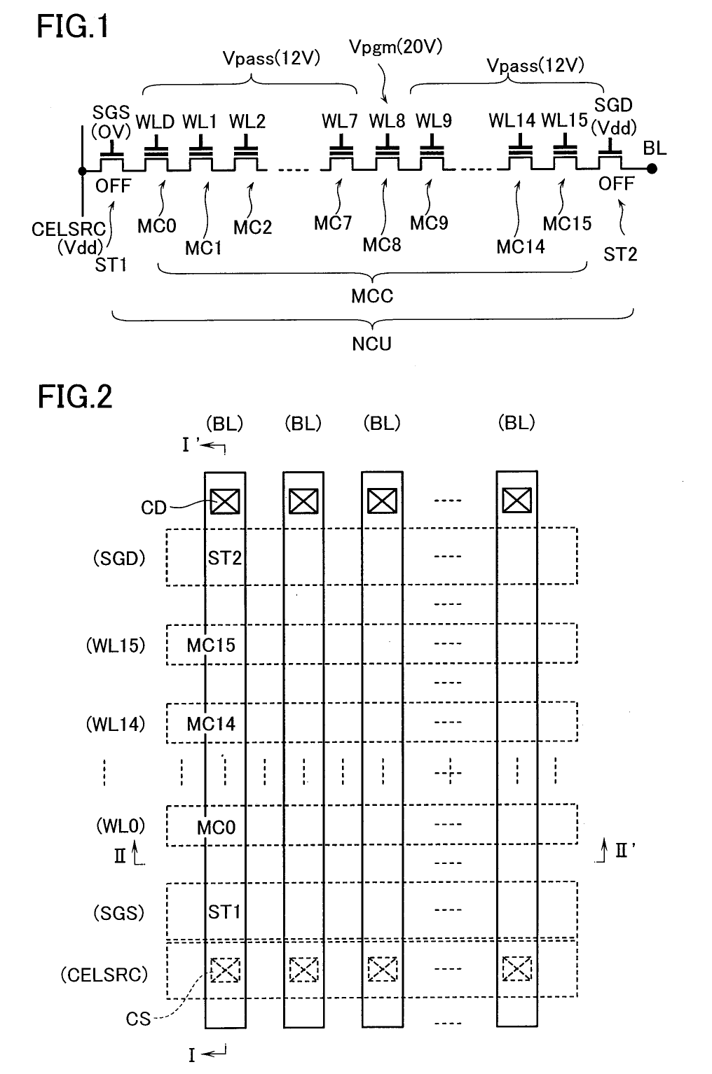

FIG. 1 is an equivalent circuit diagram of a NAND type flash memory according to a first embodiment of the present invention, and FIG. 2 is a plan view of a cell region of the same flash memory.

As shown in FIG. 1, the NAND type flash memory of this embodiment includes a NAND cell unit NCU configured by a memory cell column MCC constituted by connecting in series a plurality of memory cells MC0 to MC15 each having a stacked gate structure in which a floating gate as a charge storage layer and a control gate are stacked, and a first selection transistor ST1 and a second selection transistor ST2 which are connected respectively between one end of the memory cell column MCC and a common source line CELSRC, and between the other end of the memory cell column MCC and a bit line BL. By arranging a plurality of such NAND cell units NCU in a direction orthogonal to a direction in which the memory cell column MCC extends, a NAND cell array is configured.

Specifically, as shown in FIG. 2, in a cell region of the NAND type flash memory of this embodiment, a plurality of bit lines BL extending in the vertical direction in the drawing are formed. In the deeper layer from the bit lines BL, selection gates SGS and SGD and the common source line CELSRC which extend in a lateral direction to be orthogonal to the bit line BL, and a plurality of word lines WL0 to WL15 which are sandwiched by the selection gates SGS and SGD and extend parallel with the selection gates SGS and SGD are formed.

The memory cells MC0 to MC15 are formed on the lower side from intersection portions of the word lines WL0 to WL15 and the bit line BL, and the selection transistors ST1 and ST2 are formed on the lower side from intersection portions of the selection gates SGS and SGD and the bit line BL.

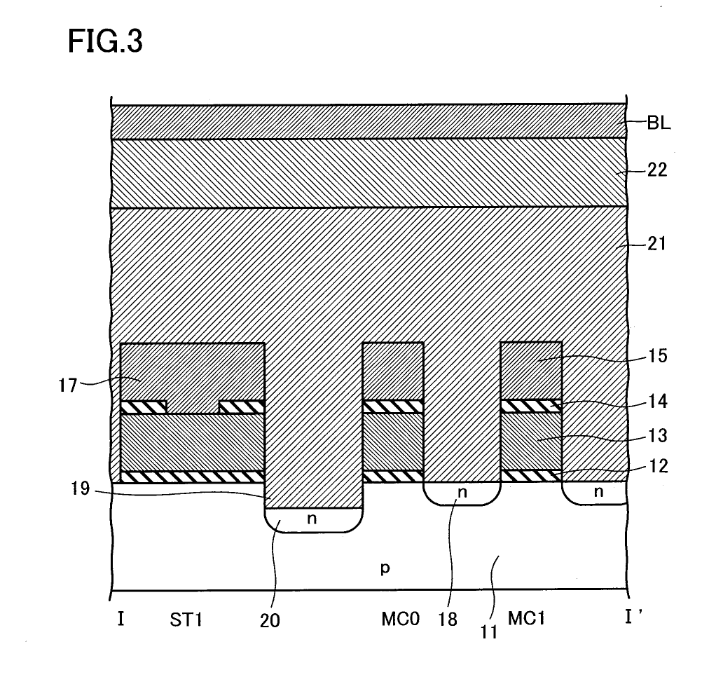

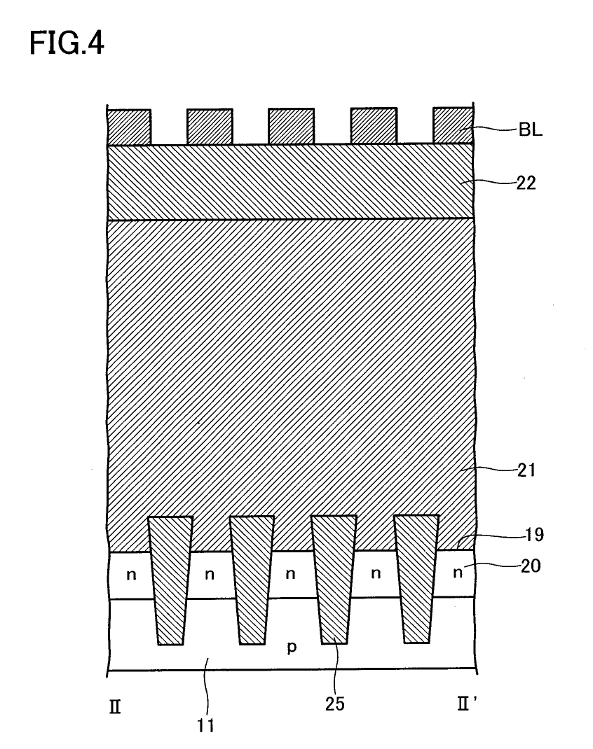

FIG. 3 is a sectional view taken along the bit line BL of the NAND type flash memory according to this embodiment (sectional view taken along I-I′ in FIG. 2), and FIG. 4 is a sectional view parallel with the word line WL between the memory cell MC0 and the selection transistor ST1 (sectional view taken along II-II′ in FIG. 2).

As shown in FIGS. 3 and 4, a gate oxide film (tunnel oxide film) 12, a floating gate 13, an inter-gate insulating film 14 and a control gate 15 are stacked on a silicon substrate 11 in this sequence, and they as well as the silicon substrate 11 configure the memory cell MC.

The floating gate 13 is separated for each memory cell MC, and the control gates 15 are formed continuously in a direction orthogonal to the bit line BL as the word lines WL or the selection gate SGS and SGD common to a plurality of memory cells MC or selection transistors ST1 and ST2, which are arranged in the direction orthogonal to the bit line BL. For the selection transistors ST1 and ST2, the floating gates 13 and the control gates 15 are short-circuited, and the transistors having normal gates 17 are configured.

In an area between the bit line BL and the bit line BL on the upper layer of the silicon substrate 11, an element isolation insulating film (STI (Shallow Trench Isolation)) 25 extending parallel with the bit line BL is formed. Thereby, stripe-shaped element formation regions separated from each other in the direction of the word line WL are defined on the upper layer of the silicon substrate 11.

Channel regions of the memory cells MC are formed in portions of the upper layers of the element formation regions, which are opposed to the floating gates 13 via the gate oxide films 12, and between these channel regions, first conductive type (for example, n-type) impurity diffusion layers 18 which become drains and sources shared by the adjacent memory cells MC are formed. A recessed portion 19 is formed on the surface of the silicon substrate 11 between the selection transistor ST1 at the common source side, and the memory cell MC0 adjacent to this, and an impurity diffusion layer 20 is formed at the lower side from the recessed portion 19. The recessed portion 19 is formed so that an edge at the side of the selection transistor ST1 reaches an edge of the gate 17 of the selection transistor ST1 at the side of the memory cell MO, and an edge at the side of the memory cell MC0 reaches an edge of the layered stack, which is constituted of the gate oxide film 12, the floating gate 13, the inter-gate insulating film 14 and the control gate 15, at the side of the selection transistor ST1. In spite of formation of the recessed portion 19, the channels of the memory cells MC0 to MC15 and the selection transistors ST1 and ST2 are formed at the surface level of the silicon substrate 11.

The layered stacks of the electrodes each constituted of the gate oxide film 12, the floating gate 13, the inter-gate insulating film 14 and the control gate 15, and the top surface of the silicon substrate between the layered stacks are covered with an interlayer insulating film 21. An interlayer insulating film 22 is formed on the interlayer insulating film 21, and the bit line BL is selectively formed on the interlayer insulating film 22.

In the NAND type flash memory thus configured, a plurality of memory cells MC extending along the direction of the word line WL are set as one page, and data write is performed by page. Specifically, at the time of data write, the substrate potential is set at 0 V first, and a write voltage Vpgm of, for example, 20 V is applied to the word line WL8 of the memory cells MC8 of the page for which write is performed, while an intermediate voltage Vpass of, for example, 12V is applied to the word lines WL0 to WL7, and WL9 to WL15 of the memory cells MC0 to MC7 and MC9 to MC15 for which write is not performed. Further, 0 V is applied to the gate of the selection transistor ST1 connected to the common source line CELSRC, and a predetermined voltage at which the gate is turned on or off in accordance with the data on the bit line BL is applied to the gate of the selection transistor ST2 connected to the bit line BL.

0 V is applied to the bit line BL connected to the memory cell MC in which “0” is to be written, and Vdd is applied to the bit line BL connected to the memory cell MC in which “1” is to be written.

Thereby, when “0” is written, the channels of the selection transistors ST2 and the memory cells MC15 to MC0 are at 0 V, and a large potential difference occurs between the floating gate and the channel of the memory cell MC8 in which data is to be written. Therefore, a tunnel current flows into the gate oxide film, and electrons are injected into the floating gate. Thereby, the threshold value of the memory cell MC8 in which the data is written increases, and the write is completed.

When “1” is written, both of the selection transistors ST1 and ST2 are brought into the OFF state, and therefore, the memory cell column MCC is brought into the floating state. Since the intermediate voltage Vpass is applied to the word lines connected to the non-selected memory cells, the channel potential of the non-selected memory cells is raised by capacitive coupling among the word lines, the floating gates and the semiconductor substrate. Thereby, the potential difference between the channels and the floating gates is made small, and erroneous write is prevented. This is called boosting.

FIG. 5 shows the relationship between the value of the intermediate voltage Vpass and the erroneous write rate when the recessed portion 19 is not formed between the selection transistor ST1 and the adjacent memory cell MC0. As shown in FIG. 5, in the non-adjacent memory cells (MC1 to MC15) which are not adjacent to the selection transistor ST1 at the common source line CELSRC side, the erroneous write rate tends to reduce as the value of the Vpass is increased. On the other hand, in the adjacent memory cell MC0 adjacent to the selection transistor ST1, the erroneous write rate reduces as the value of the Vpass rises, in the range where the value of the Vpass is low, but from a certain value, the erroneous write rate rises with increase in the value of the Vpass on the other hand.

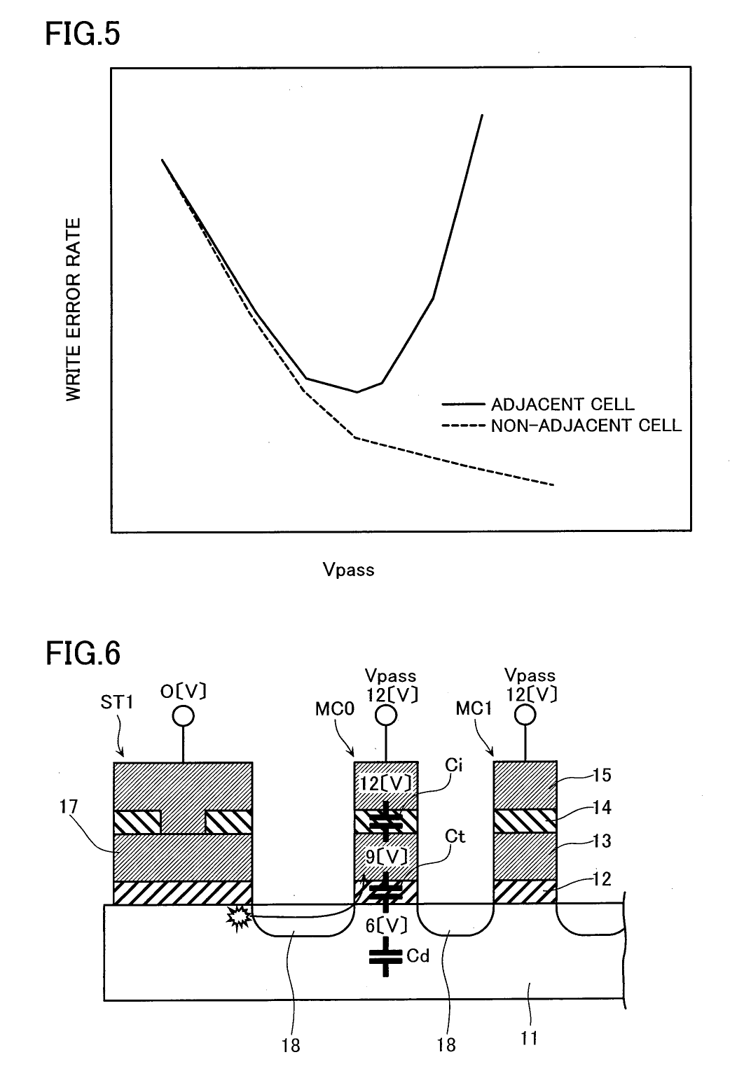

FIG. 6 schematically shows the state of occurrence of erroneous write on the occasion of boosting of a NAND type flash memory in which the recessed portion 19 is not formed. The selection transistor ST1 is in the off state as a result that 0 [V] is applied to the gate 17. 12 [V] is applied to the non-selected memory cells MC0, MC1 and the like as the Vpass. In each of the non-selected memory cells MC0, MC1 and the like, a capacitance Ci between the control gate 15 and the floating gate 13, a capacitance Ct between the floating gate 13 and an inversion layer of the silicon substrate 11 and a capacitance Cd between the inversion layer and the ground are formed, and the coupling ratio is Ci/(Ci+Ct)=½, whereas the boost ratio is Ct/(Ct+Cd)=⅔. By the capacitive coupling, the surface of the silicon substrate 11 on which the respective memory cells (MC0 to MC15) are formed is at about 6 [V], and the potential in the floating gates 13 of the non-selected memory cells MC0, MC1 and the like is about 9 [V]. In this case, a potential difference does not occur between the memory cells, but as the result that 0 [V] is applied to the gate 17 of the selection transistor ST1, a potential difference of about 6 [V] occurs between the gate 17 of the selection transistor ST1 and the memory cell MC0. Thereby, GIDL (Gate-Induced Drain Leakage) in a depletion layer near the gate of the selection transistor ST1 increases, and generated electrons are accelerated by the electric field in the depletion layer and acquire high energy. As a result, the electrons exceeding the potential barrier (about 3.2 eV) of the gate oxide film 12 of the adjacent memory cell MC0 are injected into the floating gate 13, and erroneous write occurs. As reduction in memory cells advances, and the distances between the selection transistors ST1 and the memory cells MC0 are being reduced, the influence of the erroneous write by such a mechanism becomes large, and the countermeasures against it are urgently required.

According to the NAND type flash memory according to this embodiment, the recessed portion 19 is formed on the surface of the silicon substrate 11 between the selection transistor ST1 at the source side and the memory cell MC0 adjacent to it so that its edge is in contact with the selection transistor ST1, and therefore, the gate 17 of the selection transistor ST1 and the impurity diffusion layer 20 can be separated from each other in the vertical direction without increasing the circuit area. Thereby, even if the potential difference occurs between the selection transistor ST1 and the memory cell MC0, occurrence of GIDL can be suppressed, and the occurrence rate of erroneous write due to flow of hot electrons into the floating gate 13 of the memory cell MC0 can be reduced to the value equivalent to those of the other memory cells MC1 to MC15.

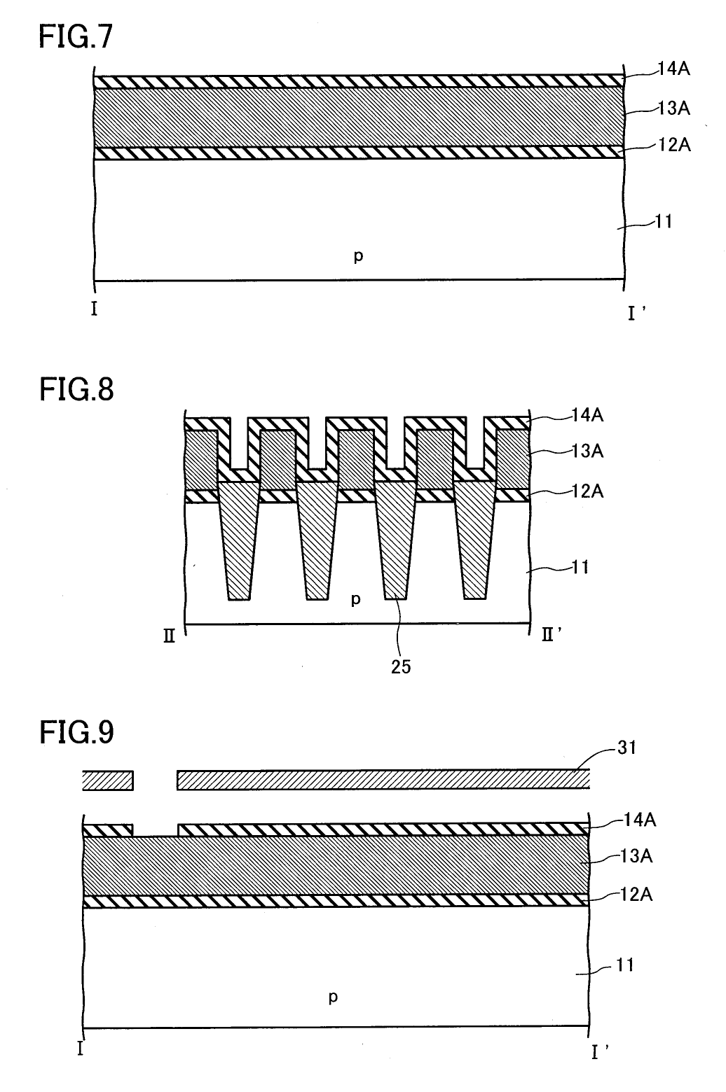

Next, based on FIGS. 7 to 14, a method for manufacturing the NAND type flash memory according to the embodiment will be described.

As shown in FIGS. 7 and 8, a well by a second conductive type (for example, p-type) impurity is first formed in the formation region for the memory cell array, of the silicon substrate 11, a silicon oxide film 12A to be the gate oxide film 12 is formed on the well, a first polysilicon film 13A to be the floating gate 13 is formed, and further, an insulating film 14A such as an ONO film (Oxide-Nitride-Oxide) and an NONON film (Nitride-Oxide-Nitride-Oxide-Nitride) to be the inter-gate insulating film 14 is formed. As shown in FIG. 8, at this stage, the silicon oxide film 12A and the first polysilicon film 13A are already separated in the directions of the word lines which will be formed later, and the element isolation insulating film 25 is formed in the direction of the bit line to be self-aligned with the films 12A and 13A. Thereby, the upper layer portion of the silicon substrate 11 is insulated and isolated in the word line direction to form the element formation regions. The insulating film 14A is formed to cover the first polysilicon film 13A and the top of the element isolation insulating film 25 entirely.

Next, after polysilicon (not illustrated) is thinly deposited on the insulating film 14A, photoresist (not illustrated) is coated entirely thereon to perform prebake, exposure is performed by using a photomask 31 for forming an opening for short-circuiting the stacked gate of the selection transistor as shown in FIG. 9, and development is performed to form a mask pattern of the photoresist. By using the mask pattern of the photoresist, etching of RIE (Reactive Ion Etching) or the like is applied to the thin polysilicon and the insulating film 14A. By the etching, in the region where the selection transistors ST1 and ST2 are formed, a part of the insulating film 14A is removed, and a part of the first polysilicon film 13A is exposed. Thereafter, the photoresist is removed.

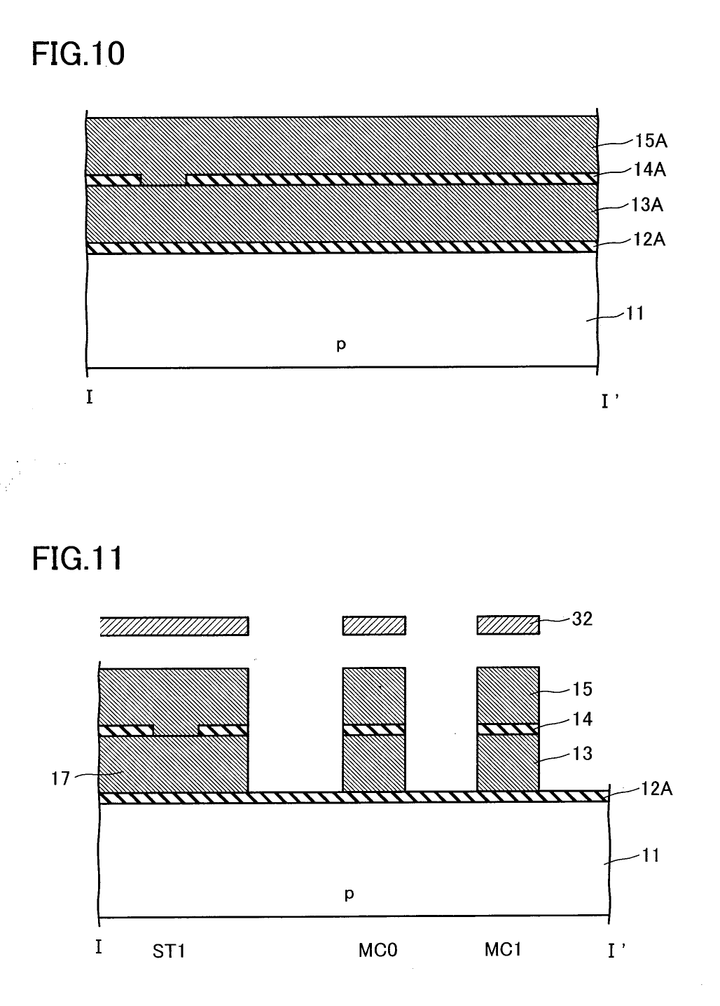

Next, as shown in FIG. 10, a second polysilicon film 15A to be the control gate 15 is formed. Thereby, the first polysilicon film 13A and the second polysilicon film 15A in the selection transistors ST1 and ST2 are connected.

Next, after photoresist (not illustrated) is coated on the second polysilicon film 15A, prebake is performed, a photomask 32 having openings for gate formation as shown in FIG. 11 is used, exposure is performed, and development is performed to form a mask pattern of the photoresist. By using the mask pattern of the photoresist, etching of RIE or the like is performed to the second polysilicon film 15A, the insulating film 14A and the first polysilicon film 13A. By the etching, the gate portions of the selection transistors ST1 and ST2 and the memory cells MC0 to MC15 are separated in the bit line direction, the floating gate 13, the inter-gate insulating film 14 and the control gate 15 are formed on the silicon oxide film 12A, and part of the silicon oxide film 12A is exposed. Thereafter, the photoresist is removed.

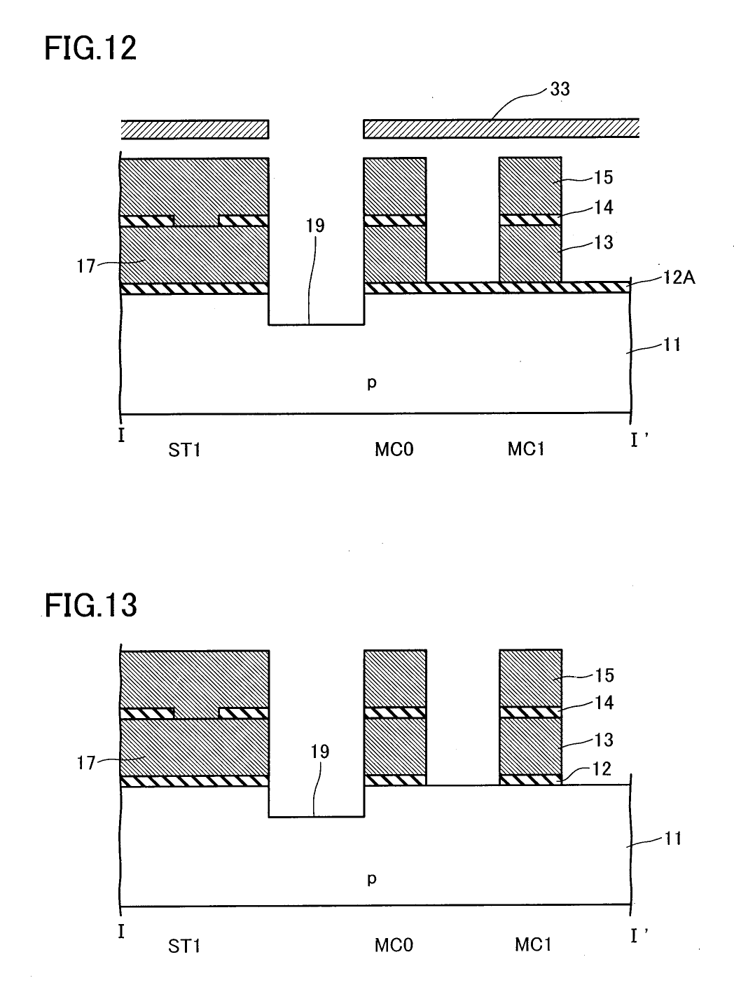

Next, after photoresist (not illustrated) is coated on the entire surface, prebake is performed, exposure is performed by using a photomask 33 having an opening for forming a recessed portion in a part of the silicon substrate 11 as shown in FIG. 12, and development is performed to form a mask pattern of the photoresist. By using the mask pattern of the photoresist, in the region between the selection transistor ST1 and the memory cell MC0, etching of RIE or the like is performed to part of the silicon oxide film 12A and the silicon substrate 11. As a result, the silicon oxide film 12A between the selection transistor ST1 and the memory cell MC0 is removed, and the surface of the silicon substrate 11 of this portion is dug by a predetermined depth and the recessed portion 19 is formed.

Next, by the same method, the silicon oxide film 12A is separated for each of the memory cells MC0 to MC15, and the gate oxide film 12 is formed as shown in FIG. 13.

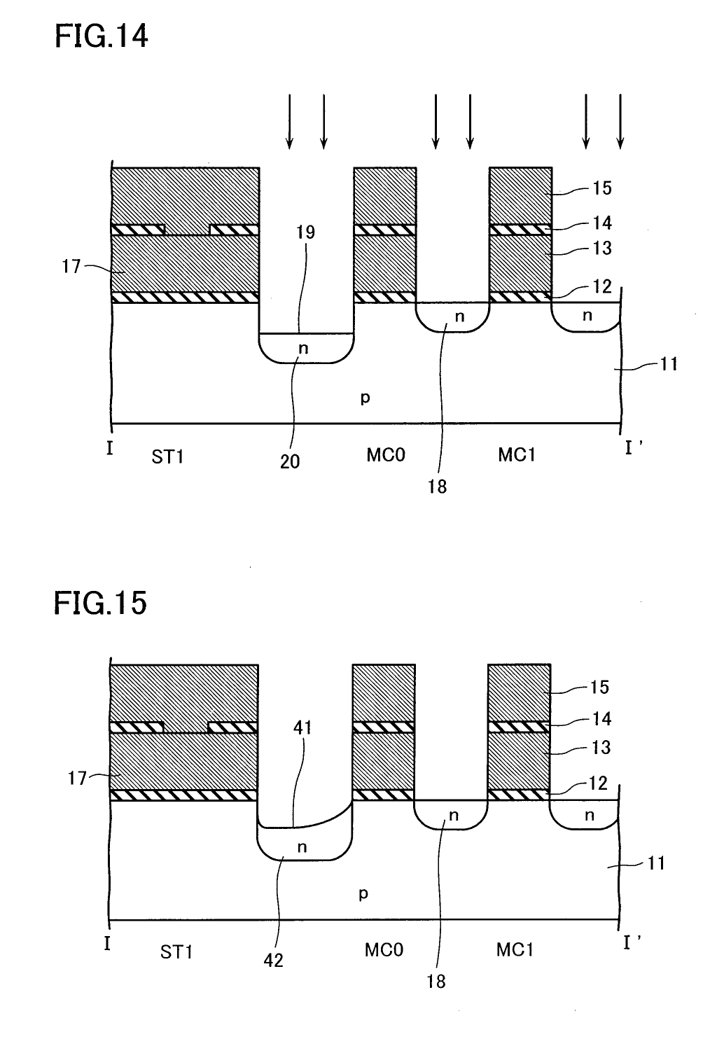

Subsequently, as shown in FIG. 14, by using the electrode portions as the mask, ion of phosphorusus (P) that is a first conductive type (for example, n-type) impurity is implanted, and thermally diffused, and impurity diffusion layers 18 are formed between the memory cells MC, and impurity diffusion layers 20 are formed between the memory cell MC0 and the selection transistor ST1, and between the memory cell MC 15 and the selection transistor ST2.

The interlayer insulating film 21 such as a silicon nitride film and TEOS (tetraethoxysilane) is formed on the layered stacks of the electrodes each constituted of the gate oxide film 12, the floating gate 13, the inter-gate insulating film 14 and the control gate 15, and on the top surface of the silicon substrate 11 between these layered stacks, the common source line CELSRC (not illustrated) is selectively formed on the interlayer insulating film 21, the interlayer insulating film 22 is formed on the interlayer insulating film 21, and further, the bit line BL is selectively formed on the interlayer insulating film 22, whereby the NAND type flash memory shown in FIGS. 3 and 4 is manufactured.

As the method for preventing occurrence of GIDL, the method for controlling the profile of the impurity concentration in the diffused layer is conceivable. This method is used for relaxing the electric field in the diffusion layer, and is used for reducing the channel concentration and the impurity diffusion layer concentration. When the channel concentration is reduced, however, the short channel effect of the selection transistor and the memory cell becomes obvious, and write and erase characteristics and reliability are degraded. Reduction of the diffusion layer concentration works in the direction to decrease GIDL, but the electric field strength in the diffusion layer may rather increase. In addition to which, diffusion probability is reduced, and more electrons with high energy are likely to occur. Therefore, the method has the problem that optimization of the profile of the impurity concentration is difficult.

In this regard, according to this embodiment, the advantage of being able to suppress occurrence of GIDL without controlling the impurity concentration is provided.

### Second Embodiment

Next, a second embodiment will be described.

FIG. 15 shows a configuration of a NAND type flash memory according to the second embodiment. The NAND type flash memory in this embodiment differs from the previous embodiment in the shape of a recessed portion 41 formed on the surface of the silicon substrate 11 between the selection transistor ST1 at the source side and the memory cell MC0. In this embodiment, the depth of the recessed portion 41 at the side of the selection transistor ST1 is larger than the depth at the side of the memory cell MC0. More concretely, the depth of the recessed portion 41 at the side of the selection transistor ST1 is the same as that in the previous embodiment, but the depth of the recessed portion 41 at the side of the memory cell MC0 is substantially zero. An impurity diffusion layer 42 is formed under the recessed portion 41.

According to such a configuration, in addition to the effect of the previous embodiment, acceleration and injection of the electrons into the floating gate 13 by the vertical electric field at the side of the memory cell MC0 can be mitigated.

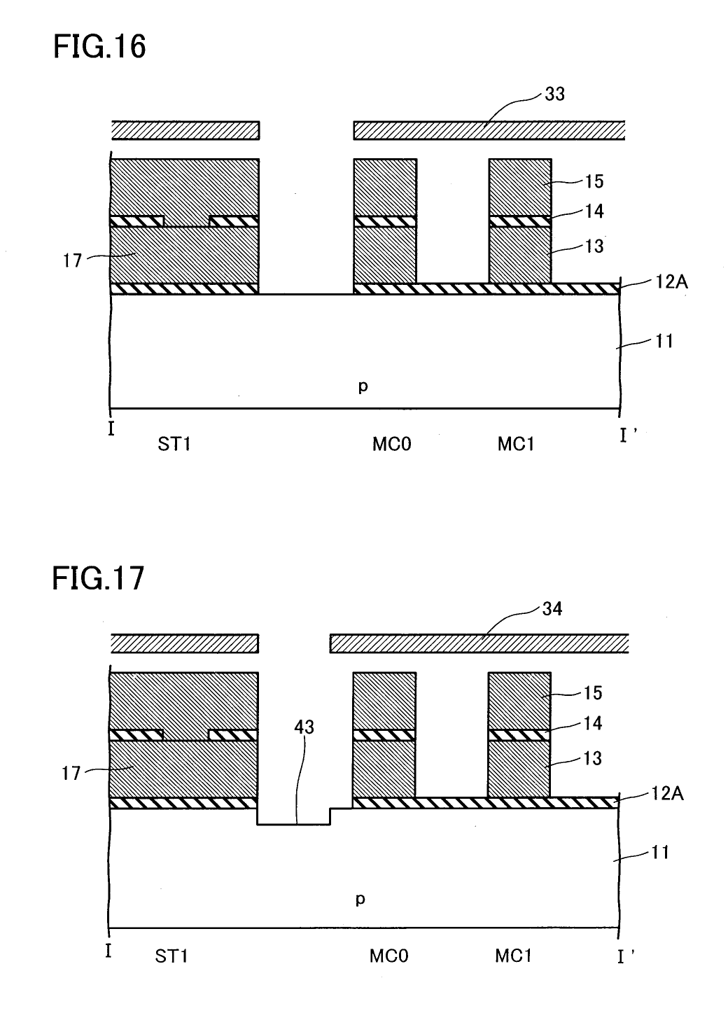

Next, based on FIGS. 16 and 17, a method for manufacturing the NAND type flash memory in this embodiment will be described.

The steps from FIGS. 7 to 11 are the same as the steps of the previous embodiment, and therefore, are omitted.

After the step of FIG. 11, photoresist (not illustrated) is coated on the entire surface, and prebake is performed. Thereafter, exposure is performed by using the photomask 33 having an opening corresponding to the distance between the selection transistor ST1 and the memory cell MC0 as shown in FIG. 16, and development is performed to form a mask pattern of the photoresist. By using the mask pattern of the photoresist, etching of RIE or the like is performed to the silicon oxide film 12A in the region between the selection transistor ST1 and the memory cell MC0. As a result, the silicon oxide film 12A between the selection transistor ST1 and the memory cell MC0 is removed.

Next, after photoresist (not illustrated) is coated on the entire surface, prebake is performed, exposure is performed by using a photomask 34 having an opening smaller than the previous photomask 33, as shown in FIG. 17, and development is performed to form a mask pattern of the photoresist. Etching of RIE or the like is performed to the silicon substrate 11 by using the mask pattern of the photoresist. As a result, a part of the silicon substrate 11 in the region at the side of the selection transistor ST1 between the selection transistor ST1 and the memory cell MC0 is dug by a predetermined depth, and a recessed portion 43 is formed. The recessed portion 43 is formed so that an edge at the side of the selection transistor ST1 is in contact with the selection transistor ST1, and an edge at the side of the memory cell MC0 is located at a position shifted to the selection transistor ST1 side from the memory cell MC0 by a predetermined distance.

Subsequently, by performing isotropic etching such as wet etching by directly using the above described mask pattern, the recessed portion 41 which has a gentle curved section as shown in FIG. 15 is formed. The edge at the side of the selection transistor ST1 of the recessed portion 41 may go under the gate 17 of the selection transistor ST1 by isotropic etching.

### Third Embodiment

Next, a third embodiment will be described.

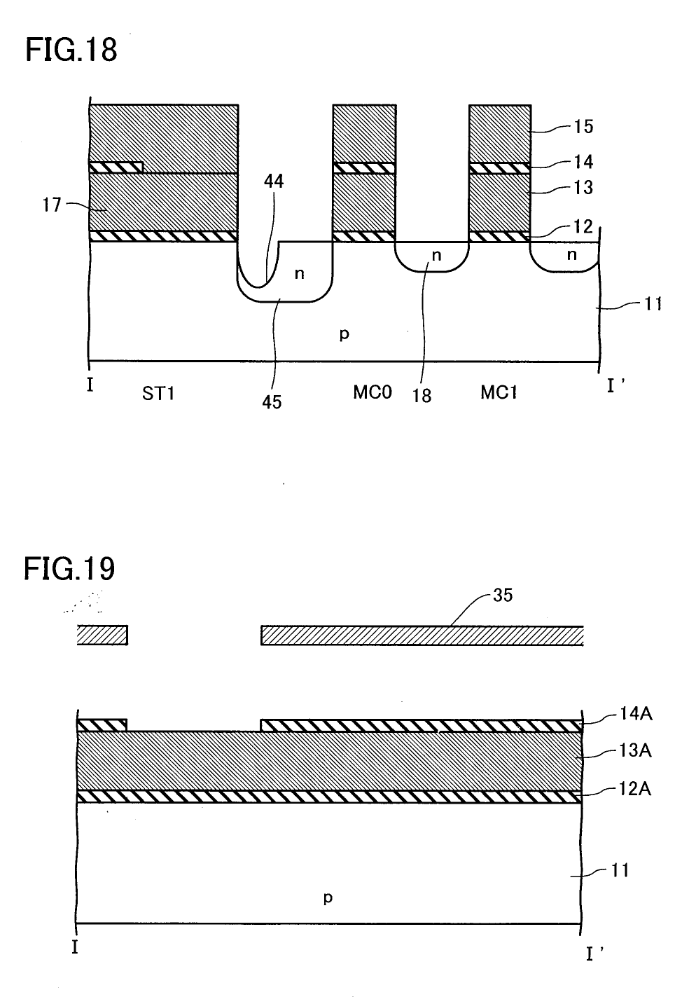

FIG. 18 shows a configuration of a NAND type flash memory in this embodiment.

This embodiment differs from the previous two embodiments in the respect that a recessed portion 44 in contact with the selection transistor ST1 is formed only at the side of the selection transistor ST1 in the surface of the silicon substrate 11 between the selection transistor ST1 and the memory cell MC0. An impurity diffusion layer 45 is formed from under the recessed portion 44 to the side of the memory cell MC0. In the selection transistor ST1, the inter-gate insulating film 14 at the side of the memory cell MC in the gate 17 does not exist.

In this embodiment, not only occurrence of GIDL can be prevented, but also acceleration and injection of the electrons into the floating gate 13 in the memory cell MC0 by the vertical electric field can be mitigated.

Next, based on FIGS. 19 to 23, a method for manufacturing a NAND type flash memory in this embodiment will be described.

After photoresist (not illustrated) is coated on the insulating film 14A first and prebake is performed, in the states in FIGS. 7 and 8, exposure is performed by using a photomask 35 having a large opening as shown in FIG. 19, and development is performed to form a mask pattern of the photoresist. By using the mask pattern of the photoresist, etching of RIE or the like is performed to the insulating film 14A. By the etching, in the region where the selection transistor ST1 is formed, a part of the insulating film 14A is removed, and a part of the first polysilicon film 13A is exposed. Thereafter, the photoresist is removed.

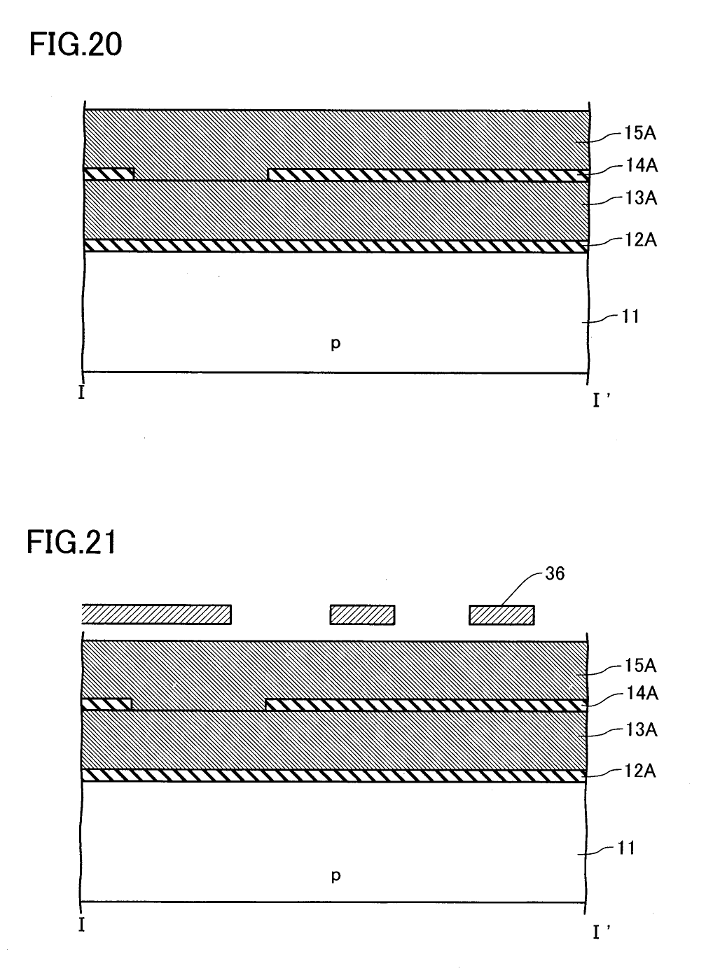

Next, as shown in FIG. 20, the second polysilicon film 15A is formed. Thereby, the first polysilicon film 13A and the second polysilicon film 15A in the region at the side of the selection transistor ST1 and the memory cell MC0 adjacent to this are connected.

Next, after photoresist (not illustrated) is coated on the second polysilicon film 15A, prebake is performed, exposure is performed by using a photomask 36 having an opening for stacked gate formation as shown in FIG. 21, and development is performed to form a mask pattern of the photoresist. By using the mask pattern of the photoresist, etching of RIE or the like is performed to the second polysilicon film 15A.

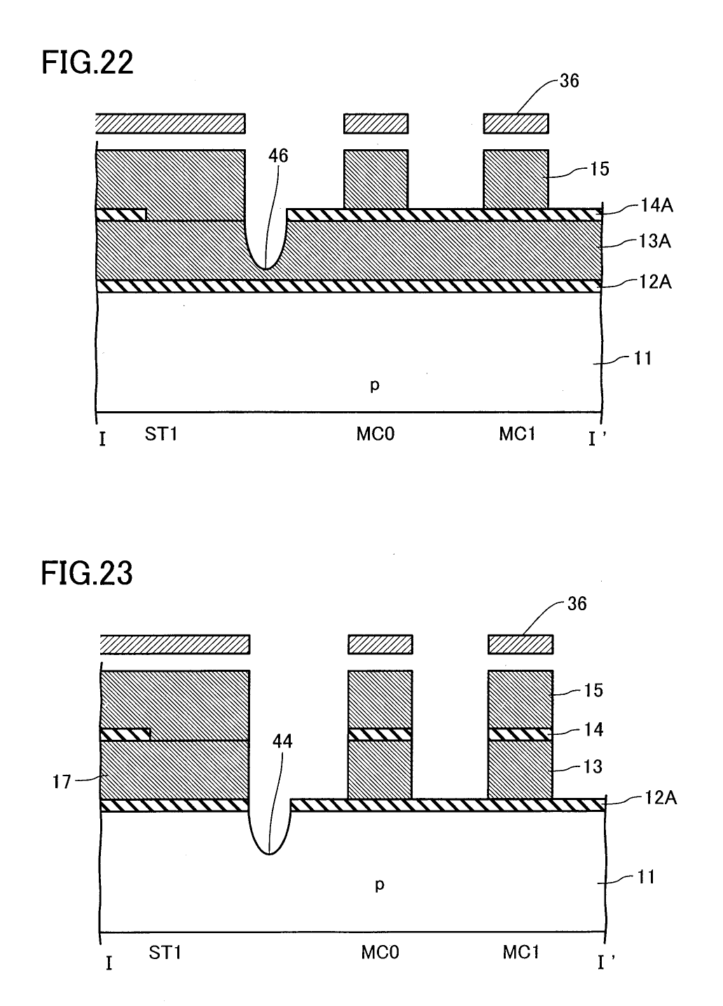

FIG. 22 is a view showing the state in which the etching is performed until the surface of the insulating film 14A is exposed. In the etching by RIE of this step in this embodiment, the etching speed of the insulating film 14A of the ONO film or the like is lower than the etching speed of the polysilicon film 13A, and therefore, etching of the region of the first polysilicon film 13A, which is not covered with the resist and the insulating film 14A, advances, and a recessed portion 46 is formed.

Thereafter, when etching for the insulating film 14A and the first polysilicon film 13A is performed, and etching advances to such an extent that the silicon oxide film 12A is exposed as shown in FIG. 23, the electrode portions such as the selection transistors ST1 and ST2, and the memory cells MC0, MC1, and the like are separated. On this occasion, etching advances faster in the region where the recessed portion 46 is formed than in the other portion. Therefore, the silicon oxide film 12A and the silicon substrate 11 are dug, and a recessed portion 44 is formed.

### Fourth Embodiment

Next, a fourth embodiment will be described.

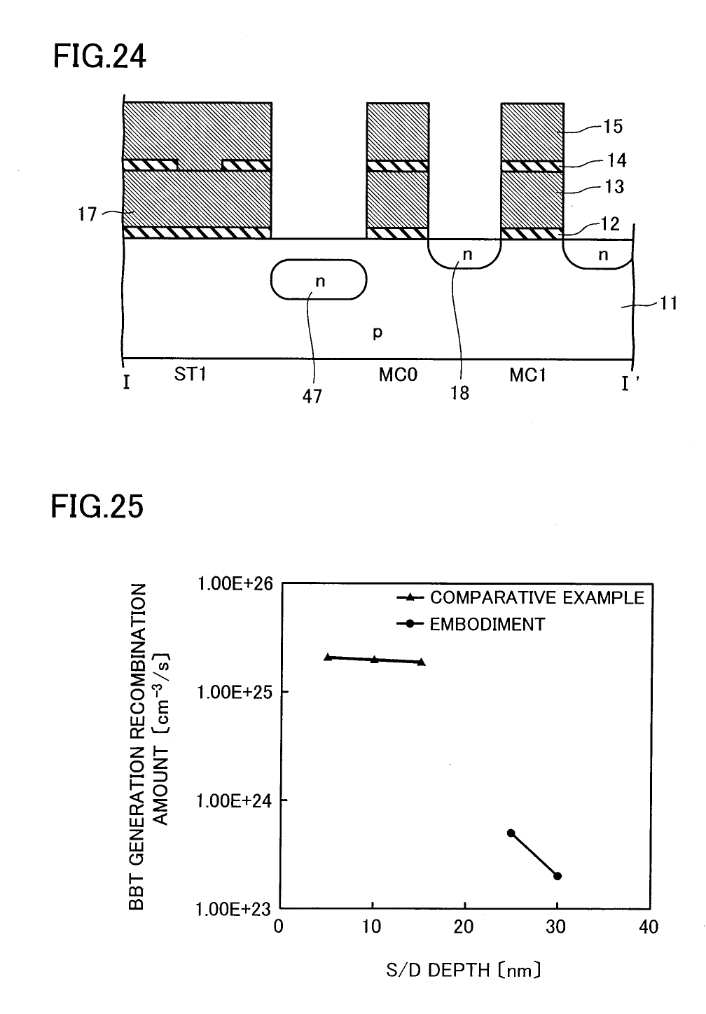

In this embodiment, an impurity diffusion layer 47 for supplying a carrier formed between the selection transistor ST1 and the memory cell MC0 is formed in the deeper layer separated from the surface layer of the silicon substrate 11 by controlling the depth of ion-implantation of an impurity (for example, n-type), as shown in FIG. 24. Specifically, the impurity diffusion region of the same conductive type as the well formed by introduction of the channel impurity exists between the impurity diffusion layer 47 and the surface of the silicon substrate 11.

FIG. 25 shows the simulated relation between the depth of the impurity diffusion layer 47 from the surface of the silicon substrate 11 and the BBT generation recombination amount. The BBT generation recombination amount is the number of carriers generated by BBT (Band to Band Tunneling) per unit time and unit volume, and it means that as the value is lower, erroneous write by GIDL is less. As is obvious from FIG. 25, the depth where the impurity diffusion layer 47 is formed is preferably 20 [m] or more, and is preferably 100 [m] or less due to the limit of the manufacture process.

### Fifth Embodiment

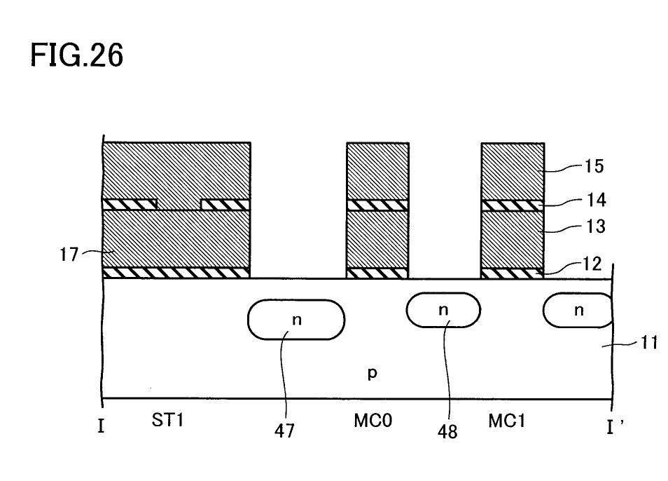

In the above described embodiment, only the impurity diffusion layer 47 formed in the silicon substrate 11 between the selection transistor ST1 and the memory cell MC0 is formed to be separated from the surface of the silicon substrate 11, but as shown in, for example, FIG. 26, impurity diffusion layers 48 in the silicon substrate 11 between the other adjacent memory cells MC and between the selection transistor ST2 and the memory cell MC15 may be formed in the deeper layer separated from the surface of the silicon substrate 11 as the impurity diffusion layer 47.

In this case, ion-implantation of the impurity diffusion layers by a mask does not need to be performed separately, and the advantage of being able to simplify the manufacture process is provided.

What is claimed is:

1. A nonvolatile semiconductor memory device, comprising:
a memory cell column formed by connecting in series a plurality of memory cells each having a structure in which a charge-storage layer and a control gate are stacked via an insulating layer on a semiconductor substrate;
a first selection transistor formed on said semiconductor substrate and connected between one end of said memory cell column and a common source line; and
a second selection transistor formed on said semiconductor substrate and connected between the other end of said memory cell column and a bit line,
wherein a recessed portion is formed on a surface of said semiconductor substrate between said first selection transistor and a memory cell adjacent to said first selection transistor, an edge at a side of said first selection transistor in said recessed portion reaches an end portion at a side of said memory cell in a gate of said first selection transistor.

2. The nonvolatile semiconductor memory device according to claim 1,
wherein an edge at a side of said memory cell in said recessed portion reaches an end portion at a side of said first selection transistor in said stacked structure of the memory cell adjacent to said first selection transistor.

3. The nonvolatile semiconductor memory device according to claim 2,
wherein said recessed portion has a substantially constant depth from the side of said first selection transistor to the side of said memory cell.

4. The nonvolatile semiconductor memory device according to claim 2,
wherein an impurity diffusion layer is formed on an underside of said recessed portion.

5. The nonvolatile semiconductor memory device according to claim 1,
wherein in said recessed portion, a depth at the side of said first selection transistor is larger than a depth at a side of said memory cell.

6. The nonvolatile semiconductor memory device according to claim 5,
wherein in said recessed portion, the depth at the side of said memory cell is substantially zero.

7. The nonvolatile semiconductor memory device according to claim 5,
wherein said recessed portion has a gentle curved section.

8. The nonvolatile semiconductor memory device according to claim 1,
wherein an edge at a side of said memory cell in said recessed portion is located at a position shifted to the side of said first selection transistor from an end portion at a side of said first selection transistor in said stacked structure of the memory cell adjacent to said first selection transistor.

9. The nonvolatile semiconductor memory device according to claim 8,
wherein an edge at a side of said memory cell in an impurity diffusion layer formed on the surface of said semiconductor substrate between said first selection transistor and said memory cell adjacent to said first selection transistor reaches the end portion at a side of said first selection transistor in said stacked structure of said memory cell.

10. The nonvolatile semiconductor device according to claim 1,
wherein channels of said plurality of memory cells and said first and second selection transistors are formed at a surface level of said semiconductor substrate.

11. A nonvolatile semiconductor memory device, comprising:
a memory cell column formed by connecting in series a plurality of memory cells each having a structure in which a charge-storage layer and a control gate are stacked via an insulating layer on a semiconductor substrate;
a first selection transistor formed on said semiconductor substrate and connected between one end of said memory cell column and a common source line; and
a second selection transistor formed on said semiconductor substrate and connected between the other end of said memory cell column and a bit line,
wherein an impurity diffusion layer for supplying a carrier formed in said semiconductor substrate between said first selection transistor and a memory cell adjacent to said first selection transistor is positioned in a deeper layer separated from a surface of said semiconductor substrate.

12. The nonvolatile semiconductor memory device according to claim 11,
wherein the impurity diffusion layer formed in said semiconductor substrate between said first selection transistor and the memory cell adjacent to said first selection transistor is positioned in a deeper layer separated from the surface of said semiconductor substrate by 20 nm to 100 nm inclusive.

13. The nonvolatile semiconductor memory device according to claim 11,
wherein impurity diffusion layers for supplying the carrier formed in said semiconductor substrate between said memory cells are positioned on the surface of said semiconductor substrate.

14. The nonvolatile semiconductor memory device according to claim 11,
wherein impurity diffusion layers for supplying the carrier formed in said semiconductor substrate between said memory cells are positioned in the deeper layer separated from the surface of said semiconductor substrate.

15. The nonvolatile semiconductor memory device according to claim 11,
wherein channels of said plurality of memory cells and said first and second selection transistors are formed at a surface level of said semiconductor substrate.

16. A nonvolatile semiconductor memory device, comprising:
a memory cell column formed by connecting in series a plurality of memory cells each having a structure in which a charge-storage layer and a control gate are stacked via an insulating layer on a semiconductor substrate;
a first selection transistor formed on said semiconductor substrate and connected between one end of said memory cell column and a common source line; and
a second selection transistor formed on said semiconductor substrate and connected between the other end of said memory cell column and a bit line,
a write voltage being applied to a control gate of a selected memory cell of said memory cell column, a pass voltage lower than said write voltage being applied to a control gate of a non-selected memory cell of said memory cell column, a ground voltage being applied to a gate of said first selection transistor, a predetermined voltage which turns on or off said second selection transistor in accordance with data on said bit line being applied to a gate of said second selection transistor, and thereby the data on said bit line being written in said selected memory cell,
wherein at least a part of a top surface of an impurity diffusion layer for supplying a carrier formed in said semiconductor substrate between said first selection transistor and a memory cell adjacent to said first selection transistor is deeper than a surface level of said semiconductor substrate.

17. The nonvolatile semiconductor device according to claim 16,
wherein channels of said plurality of memory cells and said first and second selection transistors are formed at the surface level of said semiconductor substrate.

18. The nonvolatile semiconductor device according to claim 16,
wherein a recessed portion is formed on a surface of said semiconductor substrate between said first selection transistor and the memory cell adjacent to said first selection transistor.

19. The nonvolatile semiconductor device according to claim 18,
wherein an edge at a side of said first selection transistor in said recessed portion reaches an end portion at a side of said memory cell in a gate of said first selection transistor.

20. The nonvolatile semiconductor device according to claim 16,
wherein the impurity diffusion layer for supplying a carrier formed in said semiconductor substrate between said first selection transistor and the memory cell adjacent to said first selection transistor is positioned in a deeper layer separated from a surface of said semiconductor substrate.
